(19) United States
(12) Patent Application Publication
(10) Pub. No.: US 2026/0129959 A1
(43) Pub. Date: May 7, 2026

(54) THIN FILM RESISTOR AND THIN FILM METAL-INSULATOR-METAL CAPACITOR USING SACRIFICIAL OXIDE FOR ALUMINUM BACKEND PROCESS

(71) Applicant: Microchip Technology Inc., Chandler, AZ (US)

(72) Inventors: Paul Fest, Chandler, AZ (US); Howard Simon, Gresham, OR (US); Quentin Francis, Troutdale, OR (US); Masen Kennish, Hubbard, OR (US); Taylor Petersen, Portland, OR (US); Brennan Dawson, Portland, OR (US); Zach Tillema, Portland, OR (US)

(73) Assignee: Microchip Technology Inc., Chandler, AZ (US)

(21) Appl. No.: 19/297,041

(22) Filed: Aug. 12, 2025

Related U.S. Application Data
(63) Continuation-in-part of application No. 19/185,860, filed on Apr. 22, 2025.
(60) Provisional application No. 63/716,899, filed on Nov. 6, 2024.

(51) Int. Cl. H10D 84/80; H10D 1/00; H10D 1/47; H10D 1/68

(52) U.S. Cl. CPC H10D 84/811; H10D 1/021; H10D 1/043; H10D 1/47; H10D 1/68

(57) ABSTRACT

A method is provided for forming a thin film resistor (TFR) and a thin film MIM capacitor (TFMIMCAP) in an integrated circuit (IC) device. A method comprises: forming a thin film layer over an integrated circuit (IC) structure; annealing the thin film layer; forming a thin film sacrificial hardmask on the thin film layer; forming first and second thin film elements in the thin film layer; and removing the thin film sacrificial hardmask. An integrated circuit device comprises: an integrated circuit (IC) structure; an annealed thin film layer above the IC structure; and first and second thin film elements in the thin film layer, wherein the integrated circuit device does not comprise a thin film hardmask.

### RELATED PATENT APPLICATIONS

This application is a continuation-in-part application of commonly owned United States Nonprovisional Ser. No. 19/185,860 , filed Apr. 22, 2025, the entire contents of which are hereby incorporated by reference for all purposes, which claims priority to commonly owned United States Provisional Ser. No. 63/716,899 filed Nov. 6, 2024, the entire contents of which are hereby incorporated by reference for all purposes.

### TECHNICAL FIELD

The present disclosure relates to thin film resistors (TFRs) and thin film metal-insulator-metal capacitors (TFMIMCAPs) and methods for forming TFRs and

TFMIMCAPs, in particular, TFRs and TFMIMCAPs in integrated circuits and aluminum backend processes for forming TFRs and TFMIMCAPs in integrated circuits.

### BACKGROUND

Semiconductor device technologies may integrate many different functions on a single chip. For example, analog and digital circuits may be produced on a single chip. Capacitors and resistors may be components in electrical circuits.

A thin film resistor (TFR) may include any suitable resistive film formed on or in an insulating substrate. Some common IC-integrated TFR resistive film materials include SiCr, SiCCr, TaN, and TiN. Thin film resistors (TFR), typically made of deposited homogenous metal thin film, offer technical advantages in terms of low temperature coefficient of resistance, smooth electron flow and long-term stability, which make them suitable for use in high precision radio frequency applications. Fabricating integrated TFRs typically employs the addition of numerous processing steps to the backend IC integration flow, such as several expensive photomask processes.

In semiconductor devices, it is desirable for capacitors to be small in size while having large capacitances. A MIM capacitor, such as a thin film metal-insulator-metal (TFMIMCAP) capacitor, may be capable of achieving a large capacitance while being small in size. Additionally, in semiconductor devices, it is desirable for capacitors to have a low voltage coefficient. The voltage coefficient is a measure of how much the capacitor varies with voltage. A MIM capacitor, such as a thin film metal-insulator-metal (TFMIMCAP) capacitor, may be capable of achieving a low voltage coefficient. A MIM capacitor is typically formed within the interconnect layers of an integrated circuit.

Semiconductor devices often have both capacitors and resistors integrated into a small area. Many integrated circuit (“IC”) devices incorporate thin film resistors (TFRs) or thin film MIM capacitors via fabrication of a Back-End-Of-Line (BEOL) structure. In conventional semiconductor fabrication processes, the MIM capacitor and the TFR are fabricated separately. The thin film suitable for forming the TFR is typically too resistive to be used as the MIM capacitor plate. Also, the thinness of the TFR usually imposes a particular patterning and etching process to form good electrical contact without damage to the thin resistor material. As such, adding a TFR to an integrated circuit including a MIM capacitor and vice-versa, typically results in significant additional cycle time and cost.

Integrating a thin film resistor in a semiconductor IC that uses aluminum, aluminum copper, or aluminum silicon copper as the metal interconnect layers. The specific problem is that the TFR film of choice needs to be annealed at approximately 500° C., which limits the placement of the TFR in the IC process flow. It is desirable to lower costs and have a fewer number of masking steps. Some integrations cause heavy polymer to form during the TFR etch and need to be prevented or removed.

There is a need for low-cost methods for integrating thin film resistors (TFRs) and thin film metal-insulator-metal capacitors (TFMIMCAPs) in integrated circuits.

### SUMMARY OF THE INVENTION

According to an aspect, there is provided a method comprising: forming a thin film layer over an integrated circuit (IC) structure; annealing the thin film layer; forming a thin film sacrificial hardmask on the thin film layer; and forming first and second thin film elements in the thin film layer via the thin film sacrificial hardmask; and removing the thin film sacrificial hardmask.

An aspect provides a method as in the preceding paragraph, wherein the first thin film element comprises a thin film resistor (TFR), and wherein the second thin film element comprises a thin film metal-insulator-metal capacitor (TFMIMCAP).

An aspect provides a method as in one of the preceding two paragraphs, wherein forming a thin film sacrificial hardmask comprises: forming a thin film hardmask layer over the thin film layer; forming and patterning a photomask over the thin film sacrificial hardmask layer; performing a first etch process to remove selected portions of the thin film sacrificial hardmask layer to define a thin film sacrificial hardmask, wherein the first etch process stops at the thin film layer; removing the photomask; and wherein forming the first and second thin film elements comprises: performing a second etch process using the thin film sacrificial hardmask as a hardmask to remove selected portions of the thin film layer to define the first thin film element and the second thin film element under the thin film sacrificial hardmask.

An aspect provides a method as in one of the preceding three paragraphs, wherein the thin film sacrificial hardmask comprises silicon dioxide (SiO₂), commonly referred to as ‘oxide’.

An aspect provides a method as in one of the preceding four paragraphs, comprising forming a dielectric etch stop layer over the IC structure prior to forming the thin film layer, wherein the second etch process stops at the dielectric etch stop layer.

An aspect provides a method as in one of the preceding five paragraphs, comprising: forming a Silicon Nitride (SiN), commonly referred to as ‘nitride’ insulator/capacitance layer; performing a third etch process to form a first nitride layer opening in the nitride insulator/capacitance layer over the first thin film element and a second nitride layer opening in the nitride insulator/capacitance layer over the second thin film element, thereby exposing surfaces of the first and second thin film elements, respectively; forming a metal interconnect layer, over the IC structure, comprising: a first metal interconnect element coupled to at least one of the plurality of conductive IC element contacts, a second metal interconnect extending into the first nitride layer opening to contact the underlying first thin film element, and a third metal interconnect extending into the second nitride layer opening to contact the underlying second thin film element.

An aspect provides a method as in one of the preceding six paragraphs, wherein the metal interconnect layer comprises aluminum (Al), aluminum silicon (AlSi), or aluminum silicon copper (AlSiCu).

An aspect provides a method as in one of the preceding seven paragraphs, wherein the IC structure includes a transistor including at least one conductive IC element contact connected to at least one of a source region, a drain region, and a gate region of the transistor.

An aspect provides a method as in one of the preceding eight paragraphs, wherein the thin film layer comprises silicon carbide chromium (SiCCr), silicon chromium (SiCr), chromium silicon nitride (CrSiN), tantalum nitride (TaN), tantalum silicide (Ta₂Si), or titanium nitride (TiN).

An aspect provides a method as in one of the preceding nine paragraphs, wherein annealing comprises heating the thin film layer at a temperature of at least 500° C. for at least 20 minutes.

An aspect provides a method as in one of the preceding ten paragraphs, comprising annealing the thin film layer at a time after forming the thin film layer and before forming the metal interconnect layer.

According to an aspect, there is provided an integrated circuit device comprising: an integrated circuit (IC) structure; an annealed thin film layer above the IC structure; and first and second thin film elements in the thin film layer, wherein the integrated circuit device does not comprise a thin film hardmask.

An aspect provides an integrated circuit device as in the preceding paragraph, wherein the first thin film element is a thin film resistor, and wherein the second thin film element is a thin film metal-insulator-metal capacitor.

An aspect provides an integrated circuit device as in one of the preceding two paragraphs, comprising a metal interconnect layer, over the IC structure, comprising aluminum (Al), aluminum silicon (AlSi), or aluminum silicon copper (AlSiCu), and comprising: a first metal interconnect element coupled to a conductive IC element contact, a second metal interconnect coupled to the thin film resistor, and a third metal interconnect coupled to the thin film metal-insulator-metal capacitor.

An aspect provides an integrated circuit device as in one of the preceding three paragraphs, wherein the IC structure includes a transistor including at least one conductive IC element contact connected to at least one of a source region, a drain region, and a gate region of the transistor.

An aspect provides an integrated circuit device as in one of the preceding four paragraphs, wherein the thin film layer comprises silicon carbide chromium (SiCCr), silicon chromium (SiCr), chromium silicon nitride (CrSiN), tantalum nitride (TaN), tantalum silicide (Ta₂Si), or titanium nitride (TiN).

According to an aspect, there is provided an integrated circuit device comprising: an integrated circuit (IC) structure; an annealed thin film layer, above the IC structure, comprising silicon carbide chromium (SiCCr), silicon chromium (SiCr), chromium silicon nitride (CrSiN), tantalum nitride (TaN), tantalum silicide (Ta₂Si), or titanium nitride (TiN); a thin film hardmask layer, over the thin film layer, comprising silicon dioxide (SiO₂); a thin film resistor in the thin film layer; and a thin film metal-insulator-metal capacitor in the thin film layer, wherein the integrated circuit device does not comprise a thin film hardmask.

An aspect provides an integrated circuit device as in the preceding paragraph, comprising a metal interconnect layer, over the IC structure, comprising aluminum (Al), aluminum silicon (AlSi), or aluminum silicon copper (AlSiCu), and comprising: a first metal interconnect element coupled to a conductive IC element contact, a second metal interconnect coupled to the thin film resistor, and a third metal interconnect coupled to the thin film metal-insulator-metal capacitor.

An aspect provides an integrated circuit device as in one of the preceding two paragraphs, wherein the IC structure includes a transistor including at least one conductive IC element contact connected to at least one of a source region, a drain region, and a gate region of the transistor.

### BRIEF DESCRIPTION OF THE DRAWINGS

The figures illustrate examples of methods for forming TFRs and TFMIMCAPs in integrated circuits and illustrate integrated circuit devices with TFRs and TFMIMCAPs. This flow improves the uniformity of the MIM dielectric by using a sacrificial oxide hard mask.

FIG. 1A represents a state during an IC fabrication process after formation of tungsten contacts and a chemical mechanical polish (W CMP) process at the top of the structure, which may represent conventional front-end processing up to W CMP.

FIG. 1B illustrates the example integrated circuit (IC) structure as shown in FIG. 1A, wherein a thin film layer stack is formed over the bulk insulation region and conductive contacts.

FIG. 1C illustrates the example integrated circuit (IC) structure as shown in FIG. 1B, wherein first photomasks may be formed and patterned on the thin film sacrificial hardmask layer for forming the thin film elements, in this example at locations laterally offset from the underlying transistor structure.

FIG. 1D illustrates the example integrated circuit (IC) structure as shown in FIG. 1C, wherein remaining portions of the first photomasks may be stripped to reveal the sacrificial hardmask layer.

FIG. 1E illustrates the example integrated circuit (IC) structure as shown in FIG. 1D, wherein a dry etch may then be performed to remove exposed portions of the underlying thin film layer.

FIG. 1F illustrates the example integrated circuit (IC) structure as shown in FIGURE E, wherein the sacrificial oxide hard mask is removed to prepare for MIM dielectric deposition.

FIG. 1G illustrates the example integrated circuit (IC) structure as shown in FIGURE F, wherein a nitride insulator/capacitance layer is formed over the structure.

FIG. 1H illustrates the example integrated circuit (IC) structure as shown in FIGURE G, wherein second photomasks are formed on the nitride insulator/capacitance layer and patterned over selected areas of the thin film elements.

FIG. 1I illustrates the example integrated circuit (IC) structure as shown in FIG. 1H, wherein a thin film contact etch is performed to (a) remove selected portions of the nitride insulator/capacitance layer to define nitride layers having nitride layer openings, and (b) remove selected portions of the bottom nitride etch stop layer, respectively.

FIG. 1J illustrates the example integrated circuit (IC) structure as shown in FIG. 1I, wherein the second photomasks are removed.

FIG. 1K illustrates the example integrated circuit (IC) structure as shown in FIG. 1J, wherein a first metal layer/interconnect layer is formed, referred to as a “Metal 1” layer.

FIG. 1L illustrates the example integrated circuit (IC) structure as shown in FIG. 1K, wherein a third photomask may be formed and patterned over the Metal 1 layer.

FIG. 1M illustrates the example integrated circuit (IC) structure as shown in FIG. 1L, wherein the Metal 1 layer may be etched using the third photomask to define a plurality of Metal 1 elements followed by a first inter-metal dielectric layer deposition.

FIG. 1N illustrates the example integrated circuit (IC) structure as shown in FIG. 1M, wherein a fourth photomask is applied to the inter-metal dielectric (IMD) layer.

FIG. 1O illustrates the example integrated circuit (IC) structure as shown in FIG. 1N, wherein a plurality of conductive contacts are formed in the inter-metal dielectric (IMD) layer and a Metal 2 layer is deposited and patterned on the inter-metal dielectric (IMD) layer to connect the aluminum interconnect element (now the top plate of thin film MIMCAP) with the Metal 2 layer by the plurality of conductive contacts.

FIG. 2 shows a flow chart of a method for integrating a thin film resistor (TFR) and a thin film metal-insulator-metal capacitor (TFMIMCAP) in a semiconductor integrated circuit (IC) device.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

An aspect provides a process flow to improve the uniformity of the MIMCAP dielectric by using a sacrificial oxide hard mask to pattern the TFR layer. The TFR film is placed between contact and metal 1, which allows for the approximately 500° C. anneal that sets the temperature performance for the film. The process uses just two masks to implement and can work with any IC flow that specifies aluminum interconnect. This process prevents polymer formation during the TFR etch by removing the photoresist before the TFR etch. It also allows for a chemical clean of any residual polymer because the sensitive areas are protected.

According to an aspect, there is provided techniques for integrating a thin film resistor (TFR) and a thin film metal-insulator-metal capacitor (TFMIMCAP) in a semiconductor integrated circuit (IC) device, which may provide a cost reduction as compared with conventional techniques. In some embodiments, the TFR and TFMIMCAP are formed after IC elements and IC element contacts (e.g. tungsten contacts) are formed, but before the first metal/interconnect layer (“Metal 1” layer) is formed. This may allow a TFR and TFMIMCAP anneal to be performed (e.g., to adjust the temperature coefficient of the thin film), for example at a temperature of 500° C. or above (e.g., in the range of 500°-525° C.). Thus, annealed TFRs and TFMIMCAPs may be integrated into IC devices that use aluminum interconnects (aluminum (Al), aluminum silicon (AlSi), or aluminum silicon copper (AlSiCu)), because the aluminum interconnects (which are generally not tolerant of the high temperatures experienced during a typical TFR anneal) are not formed until after the thin film anneal. The thin film anneal may be performed at any time in the process prior to depositing the first metal/interconnect layer.

Aspects of the process of forming the integrated TFR and TFMIMCAP adds two additional photomasks to the baseline IC production flow. In some aspects, the TFR and TFMIMCAP formation process includes forming a thin film etch stop layer (e.g., a SiN layer) over the IC structure (and under the thin film elements), which protects underlying IC elements (e.g., memory elements and tungsten contacts) to thereby allow chemical cleans to be performed to remove polymer residue formed during at least one etch process.

In other aspects, a nitride layer (e.g., SiN layer) and/or an oxide layer formed over the thin film layer collectively act as a hardmask during a thin film etch for defining thin film elements from a thin film layer. Providing such a hardmask may remove a process step that uses a photomask for the thin film etch, to thereby eliminate or greatly reduce the formation of polymer material during the thin film etch process, thus eliminating or reducing chemical cleans to remove such polymer material.

One aspect provides a method for forming both a thin film resistor (TFR) and a thin film metal-insulator-metal capacitor (TFMIMCAP) using the same process steps and process order. Aspects may allow for the realization of two precision devices for the manufacturing cost of one.

According to one aspect, there is provided a thin film layer used as the bottom plate of the TFMIMCAP and an aluminum alloy layer used as the top plate. The aluminum alloy layer may comprise aluminum (Al), aluminum silicon (AlSi), or aluminum silicon copper (AlSiCu). This integration may use two masks in addition to the baseline IC production flow to execute. This integration may be used with any process that uses an aluminum interconnect.

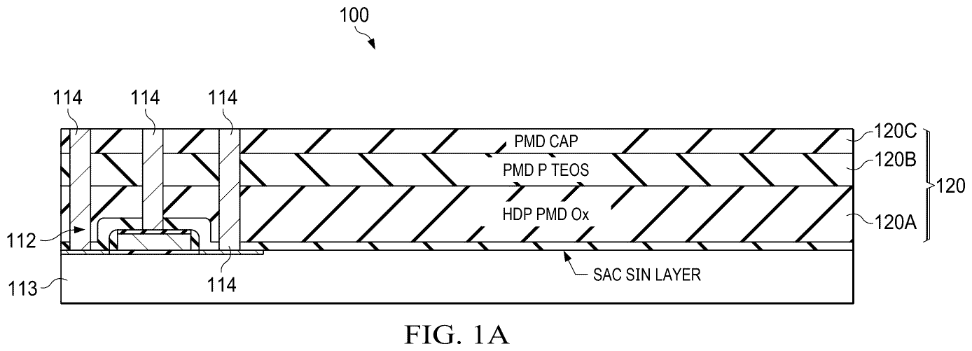

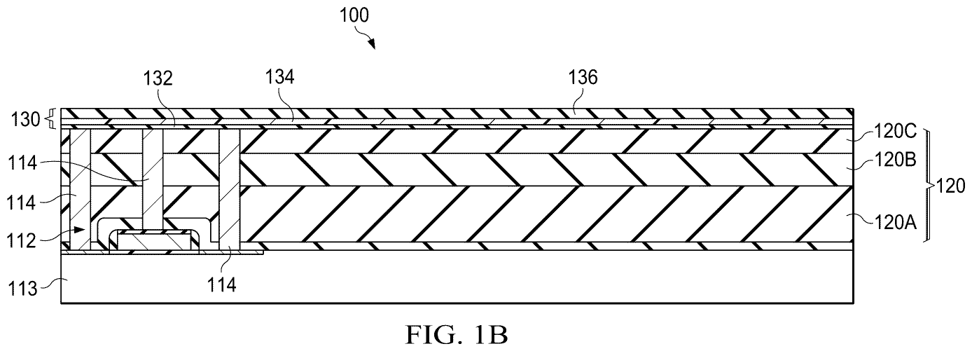

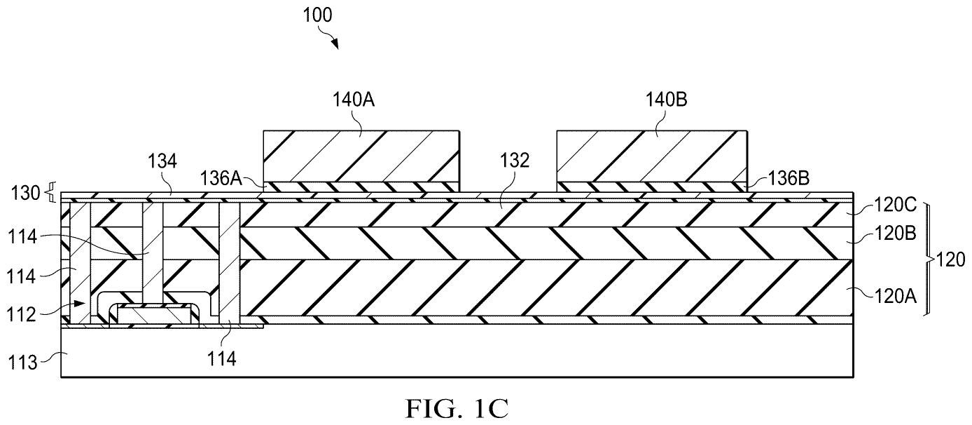

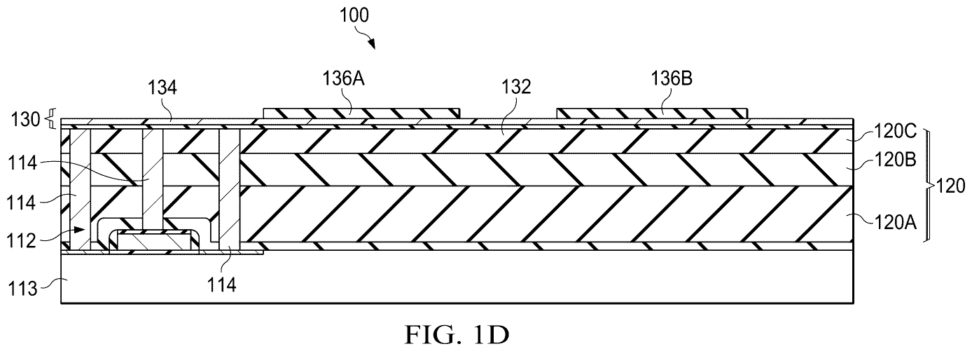

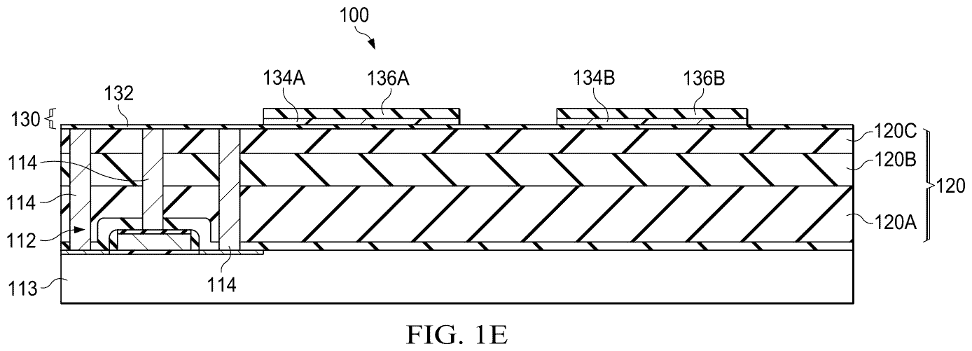

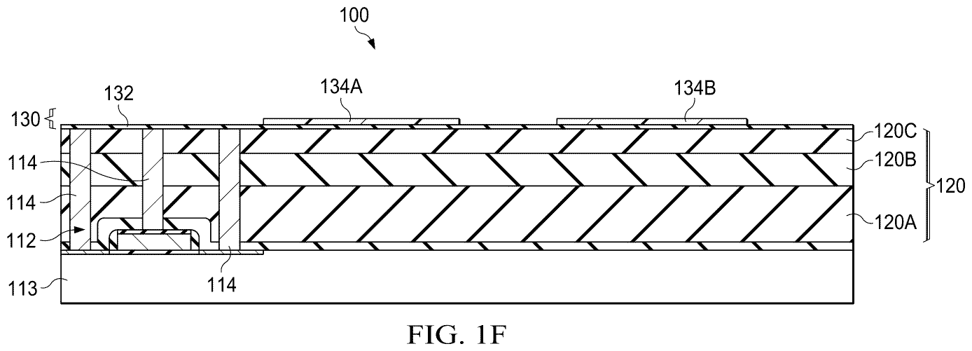

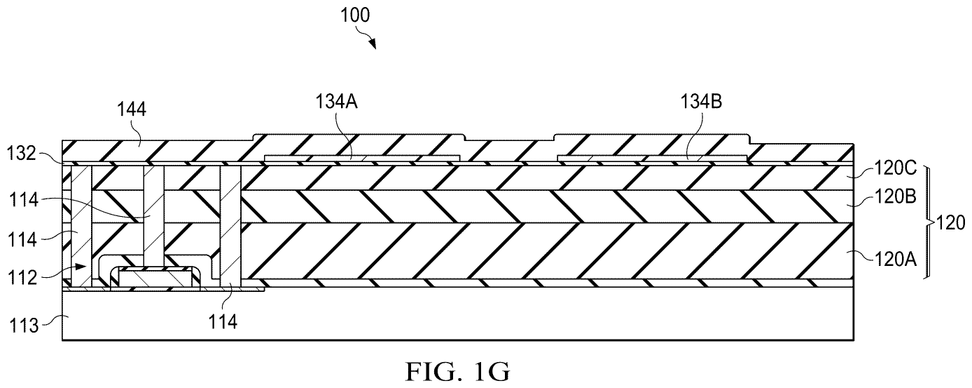

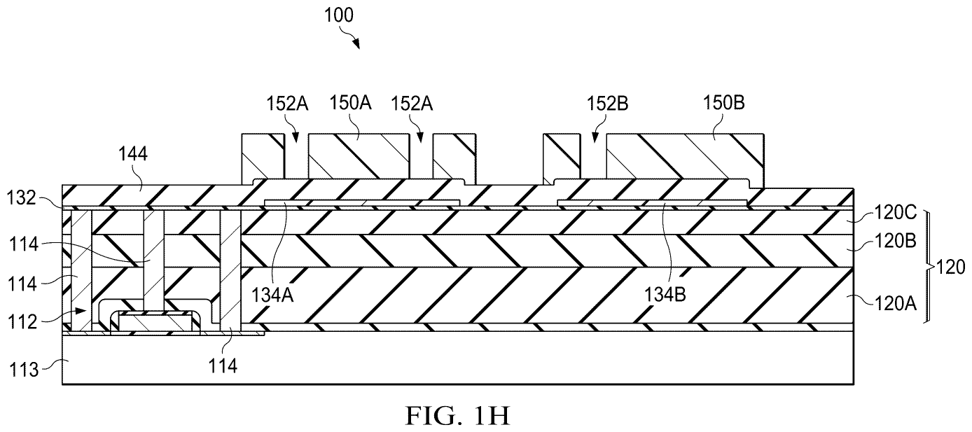

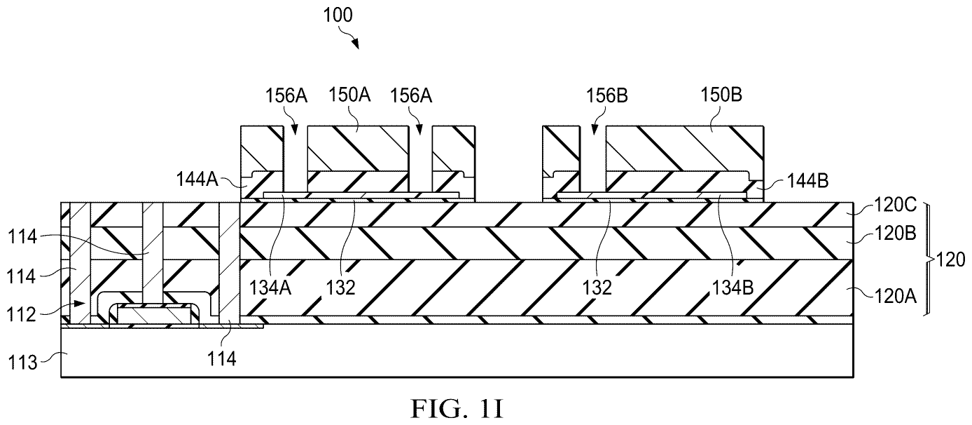

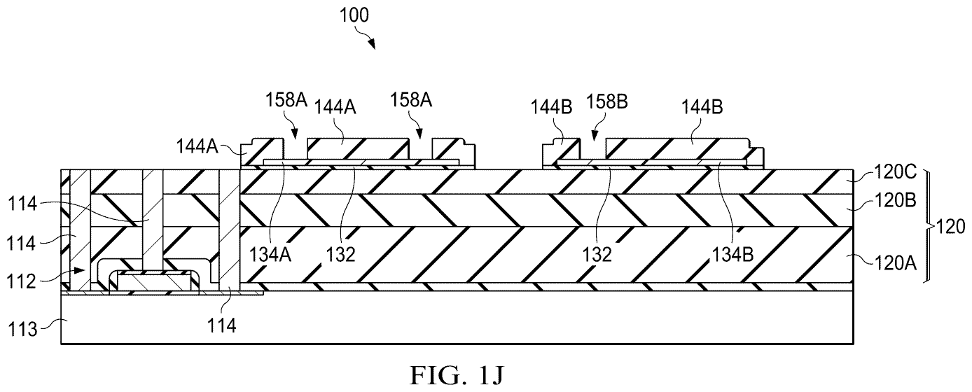

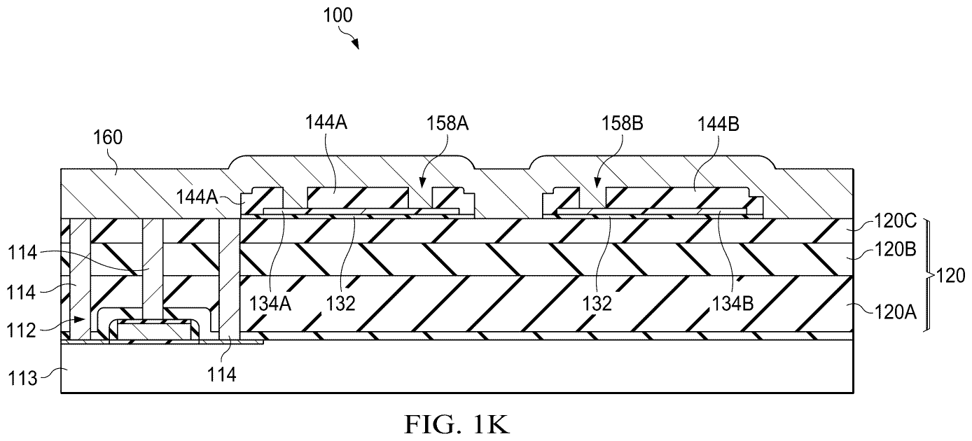

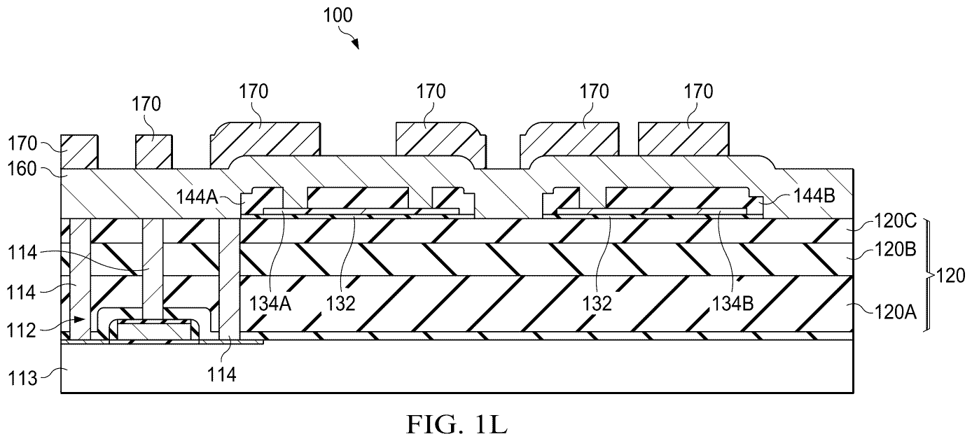

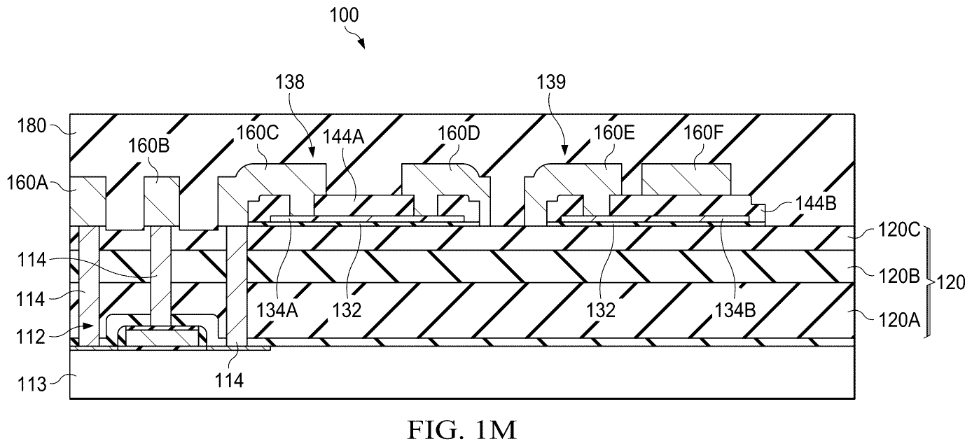

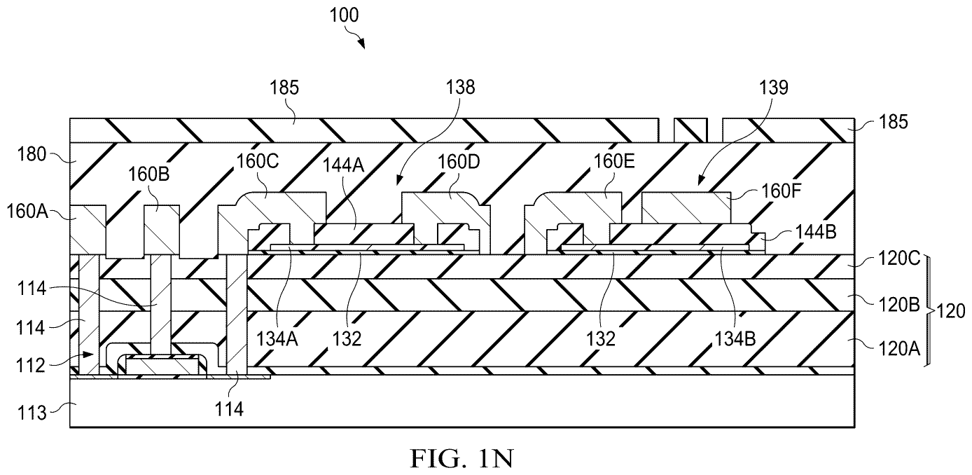

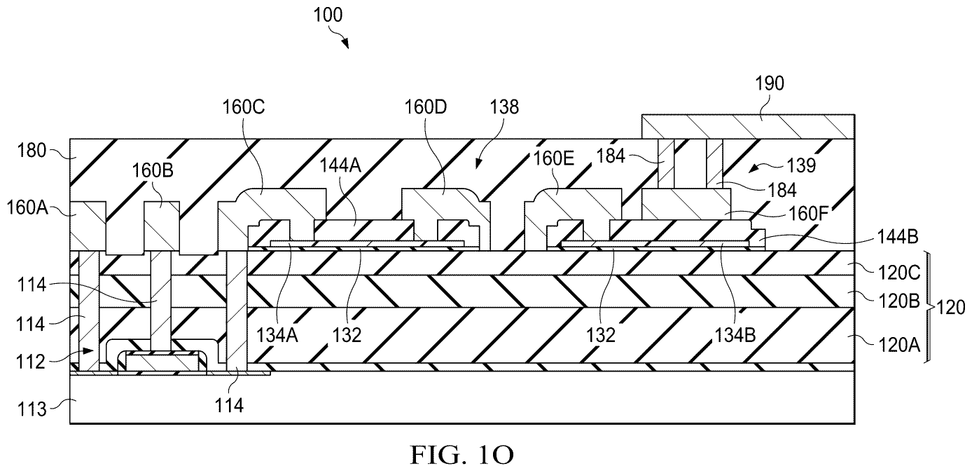

FIGS. 1A-1O illustrate a method of integrating a thin film resistor (TFR) and thin film metal-insulator-metal capacitor (TFMIMCAP) in a semiconductor integrated circuit (IC) device, according to a first example aspect. FIGS. 1A-1O further illustrate and integrated circuit device having a thin film resistor (TFR) and a thin film metal-insulator-metal capacitor (TFMIMCAP).

FIG. 1A illustrates an example integrated circuit (IC) structure 100, e.g., during the manufacturing of an IC device. In this example, the IC structure 100 includes a transistor structure 112 formed over a substrate 113, with a plurality of conductive contacts 114, e.g., tungsten contacts, extending though a bulk insulation region 120 formed over the transistor structure 112. However, the IC structure 100 may include any other IC devices(s) or structure(s), e.g., one or more full or partial memory cells or memory cell structures, and conductive contacts associated with such structures. In this example, the bulk insulation region 120 includes (a) a high-density plasma (HDP) pre-metal dielectric (PMD) oxide layer 120A, (b) a PMD oxide film 120B, e.g., PMD P TEOS (phosphorous-doped tetraethyl orthosilicate film), and (c) a PMD layer 120C.

FIG. 1A may represent a state during an IC fabrication process after formation of tungsten contacts 114 and a chemical mechanical polish (W CMP) process at the top of the structure 100, which may represent conventional front-end processing up to W CMP.

FIG. 1B illustrates the example integrated circuit (IC) structure 100 as shown in FIG. 1A, wherein a thin film layer stack 130 is formed over the bulk insulation region 120 and conductive contacts 114. First, a dielectric etch stop layer 132, e.g., a SiN layer, may be formed, e.g., to protect the tungsten contacts 114 from a subsequent thin film etch shown below at FIG. 1D. A thin film layer 134 may then be formed on the dielectric etch stop layer 132. The thin film layer 134 may comprise, SiCCr, SiCr, TaN, TiN, or any other suitable thin film material.

In some embodiments, e.g., the example embodiment shown in FIGS. 1A-1O, a thin film anneal may be performed at this point, e.g., to tune or adjust a temperature coefficient of resistance (TCR) of the thin film layer 134. For example, an anneal may be performed at a temperature of ≥500° C. In some embodiments, the thin film anneal may comprise an anneal at 515° C.±20° C. for a duration of 15-60 minutes, e.g., 30 minutes. The thin film layer 134 may be heated in an oven to a temperature unsuitable for aluminum alloy semiconductor interconnect (approximately 500° C.) for at least 20 minutes. In other embodiments, the thin film anneal may be performed at any other point in the process, prior to the deposition of the first metal layer/interconnect layer 160 (e.g., “Metal 1” layer) discussed below with reference to FIG. 1L. For example, in some embodiments, the thin film anneal may be performed after forming the sacrificial oxide hard mask 136 discussed below. In other embodiments, the thin film anneal may be performed after etching to define the thin film element 134A discussed below with respect to FIG. 1D. In other embodiments, the thin film anneal may be performed after completing the thin film contact etch described below with respect to FIG. 1K.

After the thin film anneal shown in FIG. 1B, a sacrificial oxide hard mask 136 may be formed on the thin film layer 134. In this embodiment, the sacrificial oxide hard mask 136 comprises a SiO₂ layer.

FIG. 1C illustrates the example integrated circuit (IC) structure 100 as shown in FIG. 1B, wherein first photomasks 140A and 140B may be formed and patterned on the sacrificial oxide hard mask 136 (e.g., using known photolithographic techniques) for forming a thin film, in this example at locations laterally offset from the underlying transistor structure 112. The sacrificial oxide hard mask 136 is etched to remove the exposed portions and to define sacrificial oxide hard mask 136A and sacrificial oxide hard mask 136B, and stop on the thin film layer 134.

FIG. 1D illustrates the example integrated circuit (IC) structure 100 as shown in FIG. 1C, wherein the first photomasks 140A and 140B are stripped after the sacrificial oxide hard mask 136 is etched. The dry etch may etch the sacrificial oxide hard mask 136 (stopping on thin film layer 134). The first photomasks 140A and 140B are then removed. This may avoid polymer generation during the etch of thin film layer 134. The sacrificial oxide hard mask 136A and the sacrificial oxide hard mask 136B are now configured to serve as photomasks for an etch process of the thin film layer 134. In some embodiments, a chemical clean may be used to strip the remaining portions of the first photomasks 140A and 140B, because the underlying tungsten contacts 114 are protected by the thin film element 134.

FIG. 1E illustrates the example integrated circuit (IC) structure 100 as shown in FIG. 1D, a dry etch may then be performed through the sacrificial oxide hard mask 136A and the sacrificial oxide hard mask 136B to remove exposed portions of the thin film layer 134 to define thin film element 134A and thin film element 134B. As shown, the etch may be configured to stop at the dielectric etch stop layer 132, which may protect the underlying structure, including the tungsten contacts 114.

FIG. 1F illustrates the example integrated circuit (IC) structure 100 as shown in FIG. 1E, wherein the sacrificial oxide hard mask 136A and the sacrificial oxide hard mask 136B are removed to prepare for MIM dielectric deposition. The TFR layer may be used as the bottom plate of the MIMCAP and an aluminum alloy layer may be used as the top plate. The sacrificial oxide hard mask 136A and the sacrificial oxide hard mask 136B may be used to pattern the thin film layer 134 to define thin film element 134A and thin film element 134B, which allows for a more uniform MIMCAP dielectric.

FIG. 1G illustrates the example integrated circuit (IC) structure 100 as shown in FIG. 1F, wherein a nitride insulator/capacitance layer 144, such as SiN, is formed over the structure. In some embodiments, the nitride insulator/capacitance layer 144 may comprise the same material as the dielectric etch stop layer 132. A portion of the nitride insulator/capacitance layer 144 may become the TFMIMCAP dielectric and set the capacitance and breakdown voltage of the TFMIMCAP.

FIG. 1H illustrates the example integrated circuit (IC) structure 100 as shown in FIG. 1G, wherein second photomasks 150A and 150B are formed on the nitride insulator/capacitance layer 144 and patterned over selected areas of the thin film elements 134A and 134B to define mask openings 152A and 152B respectively aligned over the thin film elements 134A and 134B. This patterns both the thin film resistor contacts and thin film MIMCAP bottom plate contact in the nitride insulator/capacitance layer 144.

FIG. 1I illustrates the example integrated circuit (IC) structure 100 as shown in FIG. 1H, wherein a thin film contact etch is performed to (a) remove selected portions of the nitride insulator/capacitance layer 144 to define nitride layers 144A and 144B having nitride layer openings 156A and 156B, respectively. The thin film contact etch may remove exposed nitride layer 144 and nitride bottom etch stop layer 132 exposing thin film elements 134A and 134B and contacts 114 as shown in FIG. 1I. This allows the next metal layer to contact the thin film resistor and the thin film MIMCAP, or other underlying conductors, wherein the thin film layer 134A will become the thin film resistor and the thin film layer 134B will become the thin film MIMCAP bottom plate.

FIG. 1J illustrates the example integrated circuit (IC) structure 100 as shown in FIG. 1I, wherein second photomasks 150A and 150B are removed by a suitable process.

The thin film contact etch may be a wet etch or a dry etch, or a combination of both. A wet etch may improve the deposition of metal during a subsequent metal deposition (e.g., the Metal 1 layer deposition shown in FIG. 1K), and may reduce the occurrence of electrical shorts (often referred to as “stringers”) along the thin film elements 134A and 134B and between adjacent metal structures (e.g., Metal 1 layer structures).

FIG. 1K illustrates the example integrated circuit (IC) structure 100 as shown in FIG. 1J, wherein the IC device processing may continue, by forming a first metal layer/interconnect layer, referred to as a “Metal 1” layer 160. In the illustrated embodiment, Metal 1 layer 160 comprises aluminum. In other embodiments, Metal 1 layer 160 may comprise copper or other metal. As shown, Metal 1 layer 160 extends into the thin film contact openings 158A, to thereby contact the thin film element 134A at disparate contact locations of the thin film element 134A, e.g., at contact locations at or near opposing lateral sides or ends of the thin film element 134A. As shown, Metal 1 layer 160 also extends into the thin film contact opening 158B, to thereby contact the thin film element 134B at the contact location of the thin film element 134B, e.g., at a contact location at or near a side or end of the thin film element 134B. Metal 1 layer 160 also extends over, and is in contact with, tungsten contacts 114.

FIG. 1L illustrates the example integrated circuit (IC) structure 100 as shown in FIG. 1K, wherein a third photomask 170 may be formed and patterned over the Metal 1 layer 160.

FIG. 1M illustrates the example integrated circuit (IC) structure 100 as shown in FIG. 1L, wherein the aluminum Metal 1 layer 160 may be etched using the third photomask 170 to define a plurality of aluminum Metal 1 elements (e.g., metal interconnect elements) 160A-160F, and the remaining photomask material 170 of FIG. 1M may then be removed. For example, as shown, the Metal 1 layer 160 may be etched to define aluminum interconnect elements 160A and 160B in contact with tungsten contacts 114, and aluminum interconnect elements 160C and 160D in contact with the disparate contact locations of the thin film element 134A, which is now a thin film resistor. In this example illustration, a first aluminum interconnect element 160C conductively connects a first contact location of the thin film element 134A (now thin film resistor) with a tungsten via 114A coupled to a source or drain region of the transistor 112, and a second interconnect element 160D conductively contacts a second contact location of the thin film element 134A (now thin film resistor) with other IC element structure(s) (not shown). The thin film element 134A and the first and second interconnect elements 160C and 160D collectively define an integrated thin film resistor, indicated at 138.

As shown in FIG. 1M, when the Metal 1 layer 160 is etched aluminum interconnect elements 160E and 160F are defined. The interconnect element 160E is in contact with the thin film element 134B (now the bottom plate of thin film MIMCAP). The aluminum interconnect element 160F (now the top plate of thin film MIMCAP) is also defined. The thin film element 134B (now the bottom plate of thin film MIMCAP), the interconnect element 160E, and the interconnect element 160F (now the top plate of thin film MIMCAP) collectively define an integrated thin film metal-insulator-metal capacitor, indicated at 139. An inter-metal dielectric (IMD) layer 180 is then added to the integrated circuit (IC) structure 100.

FIG. 1N illustrates the example integrated circuit (IC) structure 100 as shown in FIG. 1M, wherein a fourth photomask 185 is applied to the inter-metal dielectric (IMD) layer 180. The fourth photomask 185 is patterned to allow a plurality of conductive contacts to be created in the inter-metal dielectric (IMD) layer 180.

FIG. 1O illustrates the example integrated circuit (IC) structure 100 as shown in FIG. 1N, wherein a plurality of conductive contacts 184, e.g., tungsten contacts, are formed in the inter-metal dielectric (IMD) layer. A Metal 2 layer 190 is deposited on the inter-metal dielectric (IMD) layer to connect the aluminum interconnect element 160F (now the top plate of thin film MIMCAP) with the Metal 2 layer 190 by the plurality of conductive contacts 184, e.g., tungsten contacts.

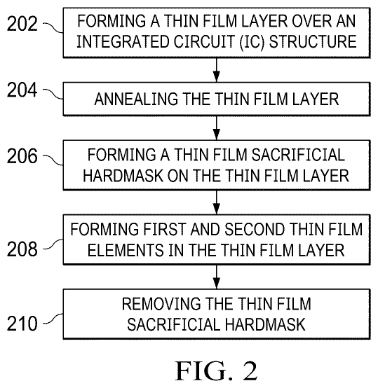

FIG. 2 shows a flow chart of a method for integrating a thin film resistor (TFR) and a thin film metal-insulator-metal capacitor (TFMIMCAP) in a semiconductor integrated circuit (IC) device. A thin film layer is formed 202 over an integrated circuit (IC) structure. The thin film layer is annealed 204. A thin film sacrificial hardmask is formed 206 on the thin film layer. First and second thin film elements are formed 208 in the thin film layer. The thin film sacrificial hardmask is removed 210.

Although examples have been described above, other variations and examples may be made from this disclosure without departing from the spirit and scope of these disclosed examples.

1. A method comprising:
forming a thin film layer over an integrated circuit (IC) structure;
annealing the thin film layer;
forming a thin film sacrificial hardmask on the thin film layer;
forming first and second thin film elements in the thin film layer via the thin film sacrificial hardmask; and
removing the thin film sacrificial hardmask.

2. The method of claim 1, wherein the first thin film element comprises a thin film resistor (TFR), and wherein the second thin film element comprises a thin film metal-insulator-metal capacitor (TFMIMCAP).

3. The method of claim 1, wherein forming a thin film sacrificial hardmask comprises:
forming a thin film sacrificial hardmask layer over the thin film layer;
forming and patterning a photomask over the thin film sacrificial hardmask layer;
performing a first etch process to remove selected portions of the thin film sacrificial hardmask layer to define a thin film sacrificial hardmask, wherein the first etch process stops at the thin film layer;
removing the photomask; and
wherein forming first and second thin film elements comprises:
performing a second etch process using the thin film sacrificial hardmask to remove selected portions of the thin film layer to define the first thin film element and the second thin film element under the thin film sacrificial hardmask.

4. The method of claim 1, wherein the thin film sacrificial hardmask comprises silicon dioxide (SiO₂).

5. The method of claim 3, comprising forming a dielectric etch stop layer over the IC structure prior to forming the thin film layer, wherein the second etch process stops at the dielectric etch stop layer.

6. The method of claim 3, comprising:
forming a nitride insulator/capacitance layer;
performing a third etch process to form a first nitride layer opening in the nitride insulator/capacitance layer over the first thin film element and a second nitride layer opening in the nitride insulator/capacitance layer over the second thin film element, thereby exposing surfaces of the first and second thin film elements, respectively;
and
forming a metal interconnect layer, over the IC structure, comprising:
a first metal interconnect element coupled to at least one of the plurality of conductive IC element contacts,
a second metal interconnect extending into the first nitride layer opening to contact the underlying first thin film element, and
a third metal interconnect extending into the second nitride layer opening to contact the underlying second thin film element.

7. The method of claim 6, wherein the metal interconnect layer comprises aluminum (Al), aluminum silicon (AlSi), or aluminum silicon copper (AlSiCu).

8. The method of claim 1, wherein the IC structure includes a transistor including at least one conductive IC element contact connected to at least one of a source region, a drain region, and a gate region of the transistor.

9. The method of claim 1, wherein the thin film layer comprises silicon carbide chromium (SiCCr), silicon chromium (SiCr), chromium silicon nitride (CrSiN), tantalum nitride (TaN), tantalum silicide (Ta₂Si), or titanium nitride (TiN).

10. The method of claim 1, wherein annealing comprises heating the thin film layer at a temperature of at least 500° C .for at least 20 minutes.

11. The method of claim 1, wherein annealing comprises heating the thin film layer to a temperature unsuitable for aluminum allow semiconductor interconnect.

12. The method of claim 6, comprising annealing the thin film layer at a time after forming the thin film layer and before forming the metal interconnect layer.

13. An integrated circuit device comprising:
an integrated circuit (IC) structure;
an annealed thin film layer above the IC structure; and
first and second thin film elements in the thin film layer, wherein the integrated circuit device does not comprise a thin film hardmask.

14. The integrated circuit device of claim 13, wherein the first thin film element is a thin film resistor, and wherein the second thin film element is a thin film metal-insulator-metal capacitor.

15. The integrated circuit device of claim 14, comprising a metal interconnect layer, over the IC structure, comprising aluminum (Al), aluminum silicon (AlSi), or aluminum silicon copper (AlSiCu), and comprising:
a first metal interconnect element coupled to a conductive IC element contact,
a second metal interconnect coupled to the thin film resistor, and
a third metal interconnect coupled to the thin film metal-insulator-metal capacitor.

16. The integrated circuit device of claim 13, wherein the IC structure includes a transistor including at least one conductive IC element contact connected to at least one of a source region, a drain region, and a gate region of the transistor.

17. The integrated circuit device of claim 13, wherein the thin film layer comprises silicon carbide chromium (SiCCr), silicon chromium (SiCr), chromium silicon nitride (CrSiN), tantalum nitride (TaN), tantalum silicide (Ta₂Si), or titanium nitride (TiN).

18. An integrated circuit device comprising:
an integrated circuit (IC) structure;
an annealed thin film layer, above the IC structure, comprising silicon carbide chromium (SiCCr), silicon chromium (SiCr), chromium silicon nitride (CrSiN), tantalum nitride (TaN), tantalum silicide (Ta₂Si), or titanium nitride (TiN);
a thin film resistor in the thin film layer; and
a thin film metal-insulator-metal capacitor in the thin film layer, wherein the integrated circuit device does not comprise a thin film hardmask.

19. The integrated circuit device of claim 18, comprising a metal interconnect layer, over the IC structure, comprising aluminum (Al), aluminum silicon (AlSi), or aluminum silicon copper (AlSiCu), and comprising:
a first metal interconnect element coupled to a conductive IC element contact,
a second metal interconnect coupled to the thin film resistor, and
a third metal interconnect coupled to the thin film metal-insulator-metal capacitor.

20. The integrated circuit device of claim 18, wherein the IC structure includes a transistor including at least one conductive IC element contact connected to at least one of a source region, a drain region, and a gate region of the transistor.
